(19) United States
(12) Patent Application Publication
(10) Pub. No.: US 2011/0000700 A1
(43) Pub. Date: Jan. 6, 2011

(54) METHOD OF CONNECTING CIRCUIT BOARDS AND CONNECTED STRUCTURE

(76) Inventors: Yoshiaki Sato, Kanagawa (JP); Kohichiro Kawate, Tokyo (JP); Tomihiro Hara, Tokyo (JP); Noriko Kikuchi, Kanagawa (JP)

Correspondence Address: 3M INNOVATIVE PROPERTIES COMPANY, PO BOX 33427, ST. PAUL, MN, 55133-3427, US

(21) Appl. No.: 12/446,518

(22) PCT Filed: Oct. 11, 2007
(86) PCT No.: PCT/US07/81073

§ 371 Date: Apr. 21, 2009

(30) Foreign Application Priority Data
Oct. 25, 2006 (JP) 2006-289932

(51) Int. Cl. H05K 1/00; H05K 3/36

(52) U.S. Cl. 174/250; 29/830

(57) ABSTRACT

A method of connecting circuit boards capable of easily accomplishing the connection maintaining reliability. A method of connection comprising the steps of obtaining a laminated body of a first circuit board, an adhesive sheet and a second circuit board, and accomplishing electric conduction between the first circuit and the second circuit by applying heat and pressure to the laminated body of the first circuit board, the adhesive sheet and the second circuit board, wherein an end of the circuit formed on at least either the first circuit board or the second circuit board is terminated at a position separated away from an end of the substrate, and the adhesive of the adhesive sheet is partly arranged between the end of the substrate of the circuit board and the end of the circuit so as to be adhered to the opposing circuit board.

### TECHNICAL FIELD

The present invention relates to a method of connecting circuit boards and to a connected structure.

### BACKGROUND

Electronic devices such as digital cameras, cell phones and printers, in many cases, use circuit boards such as flexible circuit boards (e.g., flexible printed circuit boards (FPCs)) that are joined together. These electronic devices have been realized in ever small sizes and make it necessary to connect circuit boards having wirings maintaining ever fine pitches.

The circuit boards have heretofore been connected by using a hot-melt adhesive containing electrically conducting particles. In effecting the connection relying upon the thermocompression bonding, a sufficiently large contact surface pressure is produced between the conductor at the end of the circuit of the circuit board and the electrically conducting particles, and the connection is accomplished maintaining reliability between the electrically conducting particles and the conductor at the end. As the pitch becomes narrow among the conductors of the circuit, however, the electrically conducting particles often cause the conductors to be connected and short-circuited. Therefore, it has been urged to develop a method of connecting the circuit boards together maintaining a high degree of reliability without the problem of short-circuiting.

Circuit boards having a fine pitch have now been connected together via an adhesive. According to this method, an adhesive which thermally softens or, depending upon the cases, thermally cures is arranged between the two circuit boards, and is thermocompressively bonded so as to be softened or fluidized, first, enabling the connection portions to come in contact. Depending upon the cases, the adhesive is further heated so as to be cured to establish the connection between the circuit boards. According to this method, the connection is accomplished in a state where the adhesive is interposed among the connection portions, and there arouses no problem of short-circuiting even when the pitch is fine between the connection portions. Further, the connection portions are supported by an adhesive film and are fixed enhancing the reliability of connection since the connection is not disrupted by the external stress. Here, it is desired that the connection portions are thermocompressively bonded together at a low temperature and with a low pressure to decrease damage to the circuit boards. However, when the thermocompression bonding is effected at a low temperature and with a low pressure and, particularly, when the adhesive is softened to a low degree by the heat, a thin layer of adhesive is formed between the connection portions, and it is not easy to accomplish the contact between the connection portions. In order to solve this problem, JP-A-2002-97424 proposes to roughen the surfaces of at least one side of the connection portions of the circuit boards that are to be connected. This increases the contact pressure at the protruded portions at the time of thermocompression bonding, accomplishes reliable contact and, as a result, prevents defective connection.

According to the above method, working such as embossing must be effected at the connection portions of the circuit boards requiring an additional step of production. It has, therefore, been desired to develop a method which does not require the additional step and is capable of obtaining the effect equal to or more than that of the above-mentioned method. Besides, when the stress acts in a direction of exfoliating the circuit board, this force directly acts on the electric contact surfaces between the circuits (wirings), and the electric conduction tends to be destroyed from the ends of the contact surfaces.

### SUMMARY

It is therefore an object of the present invention to provide a method of connecting circuit boards capable of achieving easy connection and maintaining reliability without requiring any additional step such as embossing, and a connected structure obtained by the above connection method.

### BRIEF DESCRIPTION OF THE DRAWINGS

FIG. 1 is a top perspective view of an embodiment of a circuit board that can be used in the method of the present invention.

FIGS. 2a-2c illustrate shapes near the end of the circuit board of this embodiment.

FIGS. 3a-3c illustrate shapes near the end of the circuit board of this embodiment.

FIGS. 4a-4c illustrate shapes near the end of the circuit board of this embodiment.

FIGS. 5a-5c show steps in a method of connection according to an embodiment of the present invention.

FIGS. 6a-6c show a sectional view of shapes near the ends of the circuit boards of this embodiment.

FIG. 7 is a sectional view illustrating an embodiment of a structure connected by the method of connecting circuit boards of one embodiment of the present invention.

FIGS. 8a-8c schematically illustrate a state wherein the circuits that are connected to a resistance measuring device.

FIGS. 9a-9a are graphs illustrating the effect of heat cycles on the connected structure.

FIG. 10 is a graph illustrating a relationship between the time required for contacting the conductors by the connection method of the invention and the overlapping length of the conductors.

FIG. 11 is a diagram schematically illustrating a testing sample for confirming the strength of adhesion.

### DETAILED DESCRIPTION OF THE PREFERRED EMBODIMENTS

The invention provides the following embodiment.

(1) A method of connection comprising:

opposing a first circuit board having one or more first circuits provided on a substrate thereof to a second circuit board having one or more second circuits formed on a substrate thereof via an adhesive sheet containing a thermoplastic adhesive component in a manner that the first circuit is partly overlapped on part of the second circuit, and that the adhesive sheet is partly arranged on a region where the first circuit and the second circuit are overlapped one upon the other to thereby obtain a laminated body of the first circuit board, the adhesive sheet and the second circuit board; and

accomplishing electric conduction between the first circuit and the second circuit by applying heat and pressure to the laminated body of the first circuit board, the adhesive sheet and the second circuit board;

wherein an end of the circuit formed on at least either the first circuit board or the second circuit board is terminated at a position separated away from an end of the substrate; and

the adhesive of the adhesive sheet is partly arranged between the end of the substrate of the circuit board and the end of the circuit so as to be adhered to the opposing circuit board.

(2) The method of connection as described in (1) above, wherein the ends of both of the first circuit and the second circuit are of a linear shape, and the length of wiring in a region where the first circuit and the second circuit are overlapped one upon the other is 0.05 to 1.4 mm.

(3) The method of connection as described in (1) above, wherein the end of at least either one of the first circuit or the second circuit is of a nonlinear shape.

(4) The method of connection as described in any one of (1) to (3) above, wherein the viscosity of the adhesive sheet at a temperature of when being heated is 1,000 to 50,000 Pa·s, and the glass transition temperature (Tg) thereof is 60° C. to 200° C.

(5) The method of connection as described in (4) above, wherein the temperature of the adhesive sheet when being heated is 150 to 250° C.

(6) The method of connection as described in any one of (1) to (5) above, wherein the adhesive component in the adhesive sheet includes a thermoplastic adhesive component as well as a thermosetting adhesive component, and is cured at the time of being connected and/or after connected.

(7) The method of connection as described in any one of (1) to (6) above, wherein the conductor wirings constituting the circuits of the circuit boards are treated on the surfaces thereof by being plated with tin, gold, nickel, or with two layers of nickel and gold.

(8) The method of connection as described in any on of (1) to (7) above, wherein at least either one of the first circuit board or the second circuit board is a flexible circuit board.

(9) A connected structure produced by the connection method as described in any one of (1) to (8) above.

The “viscosity of the adhesive sheet” is calculated from the thickness (h(t))(meters (m)) of the adhesive sheet of when a circular sample of the adhesive sheet having a radius r (meters (m)) is arranged between two pieces of horizontal flat plates while exerting a predetermined load F(N) thereon at a measuring temperature T(° C.) and after a time t (seconds) has passed. It is calculated from the following formula, h(t)/h₀=[(4h₀²Ft)/(3πηr⁴)+1]^{-1/2}, wherein hₒ is an initial thickness (meter (m)) of the adhesive sheet, h(t) is a thickness (meter (m)) of the adhesive sheet after t seconds, F is a load (N), t is a time (seconds) from when the load F is exerted, η is a viscosity (Pa·s) at the measuring temperature T° C., and r is a radius (meter (m)) of the adhesive sheet.

The “glass transition temperature (Tg) of the adhesive sheet” is measured by the dynamic viscoelastic analysis (DMA) of the adhesive composition of the adhesive sheet. The sample for the DMA measurement has a size of 30 mm×5 mm×0.06 mm, and a measurement is taken every 12 seconds at a frequency of 1 Hz in an expansion and contraction mode with an amplitude of 0.5% distortion while elevating the temperature at a speed of 5° C./minute. From the stored modulus of elasticity E′ and the loss modulus of elasticity E″ found from the DMA measurement, the glass transition temperature (Tg) is found as a temperature that becomes a peak at tan δ=E′/E″.

In the present invention, the circuits to be connected are only partly overlapped maintaining small the contact areas of the conductors to be connected. Therefore, the contact pressure becomes high during the thermocompression bonding operation, and the conductive connection is easily accomplished.

Further, it is a trend to use an adhesive which exhibits a high viscosity at high temperatures in order to improve reliability of the adhesive that constitutes the adhesive sheet. In this case, too, the conductive connection can be easily accomplished.

The end of the circuit on the circuit board that is to be connected is terminated at a position separated away from the end of the substrate. Therefore, the adhesive is adhered to the opposing circuit board over the whole portion near the end of the substrate featuring stable adhesion at the connection portion while preventing external stress from directly acting on the conductively connected portion. Accordingly, the electrically conductive state of the connected structure is not broken by the external force such as bending stress exerted on the circuit boards.

When either one of the circuit boards to be connected is a flexible circuit board, this substrate is connected in a deflected manner on the region where there is no circuit on the substrate. Therefore, the contacting pressure of the conductor increases due to the restoring force of the substrate which restores from the deflected state, and the connection strength further increases.

In producing the circuit boards, the connection portions can be reliably contacted together at the time of thermocompression bonding without requiring additional production step such as embossing, and a highly reliable connection is obtained.

The present invention will now be described below by way of an embodiment to which, however, the invention is in no way limited.

The circuit board to be connected by the connection method of the present invention has an end of the circuit terminated at a position separated away from the end of the substrate. There is no particular limitation on the circuit board so far as it includes the above wiring. Suitable examples of the circuit board include flexible circuit board (FPC), circuit board based on a glass epoxy, circuit board on an aramide, circuit board based on a bismaleimide·triazine (BT resin), glass board or ceramic board having a wiring pattern formed by using ITO, aluminum or fine metal particles, and a rigid circuit board such as a silicon wafer having junction portions of a metal conductor on the surface, which, however, are not to impose limitation. In one aspect of the invention, the mutual connection can be accomplished even relying on the thermocompression bonding at a low temperature and under a low pressure. The embodiment of the invention can be advantageously applied to the circuit boards that are subject to be easily damaged by the thermocompression bonding. Therefore, the method of the invention is particularly advantageous when at least one of the circuit boards is a flexible circuit board (FPC). The circuit boards mutually connected by the method of the present invention can be used for such electronic devices as digital cameras, cell phones, printers and the like.

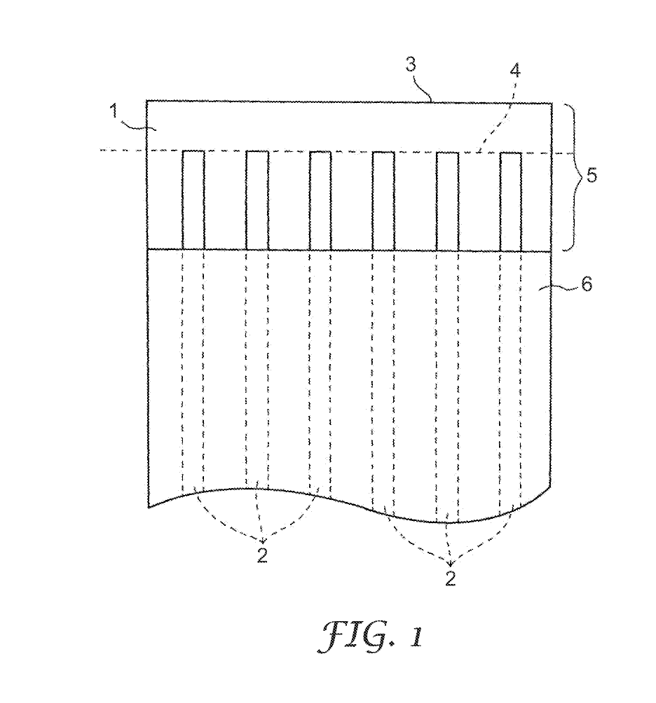

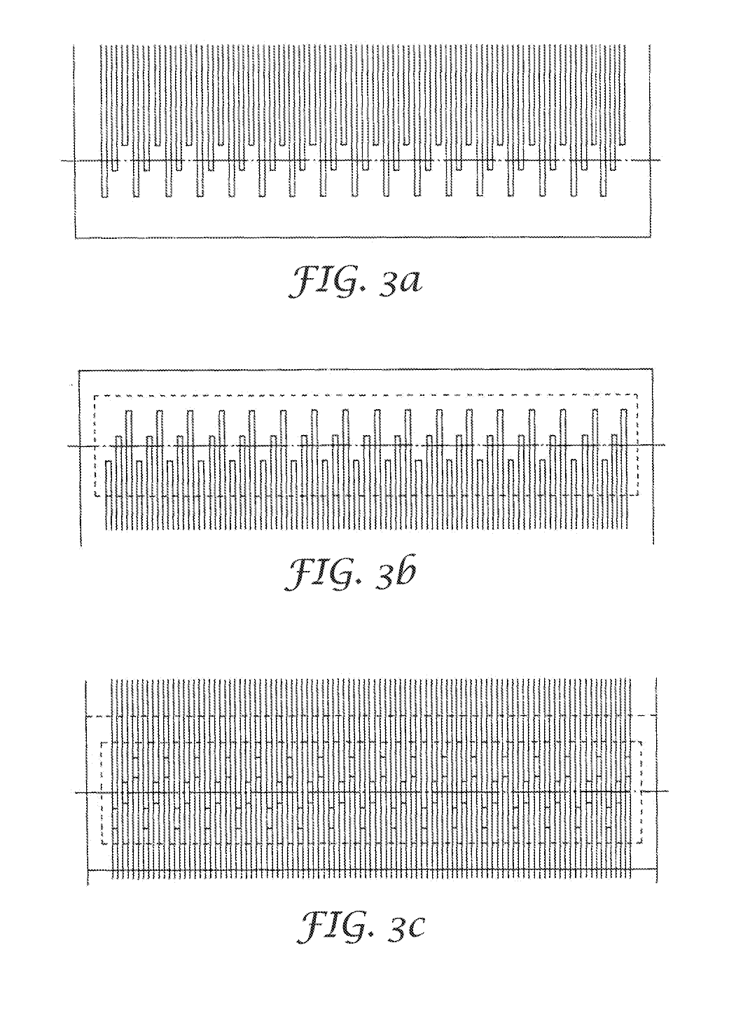

The invention will be described below with reference to the drawings. Though the following description uses a flexible circuit board with reference to the drawings, it should be noted that the circuit board used in the invention is in no way limited thereto. FIG. 1 is a top view of the circuit board that can be used for the method of the present invention. The circuit board 10 (FPC) has wirings 2 formed on the front surface of a substrate 1 (resin film) with their ends being terminated at the end 4 of the circuit on the inside of an end 3 of the substrate. The circuit board is usually covered with an insulating film 6 to maintain insulation except a connection portion 5. Drawing (a) illustrates a wiring shape of a first circuit board, Drawing (b) illustrates a wiring shape of a second circuit board, and Drawing (c) illustrates a wiring shape in the connected state. When the wirings are of a linear shape as shown in FIGS. 1 and 3, it is desired that the length over which the wirings are overlapped one upon the other is 0.05 to 1.4 mm. The above length over which the wirings are overlapped one upon the other makes it possible to maintain a sufficient contact pressure while maintaining reliable electric conduction.

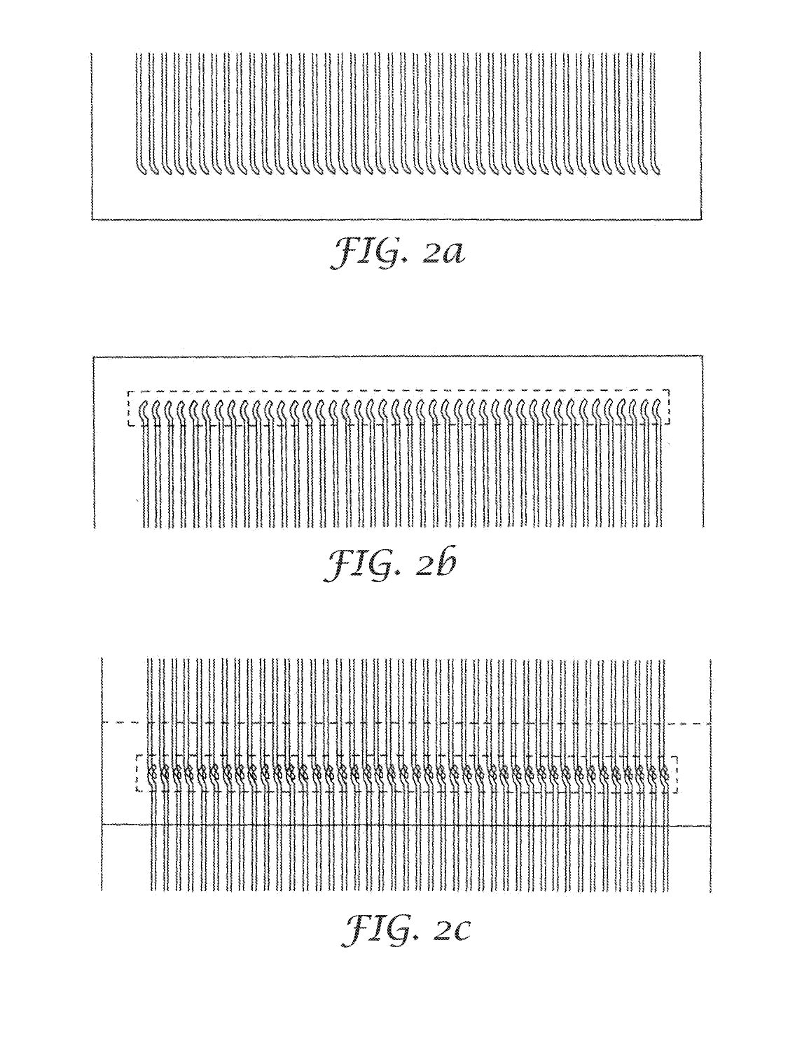

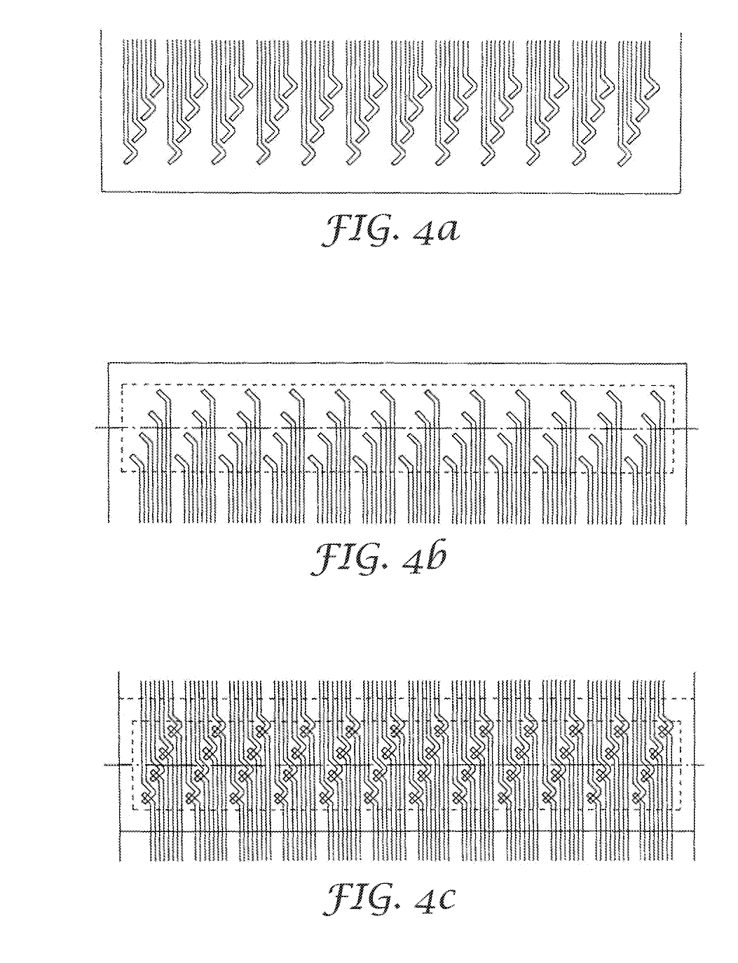

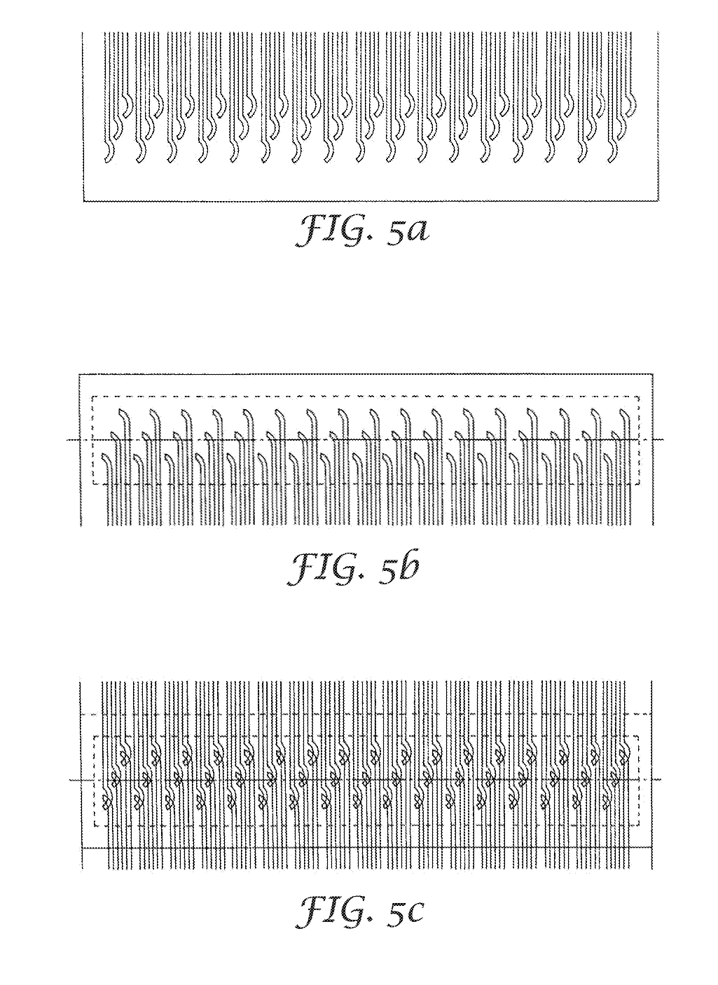

The ends 4 of the circuits may be of a linear shape as shown in FIG. 1 but may also be of a nonlinear shape as shown in FIG. 2. As shown in FIGS. 1 and 2, further, the ends 4 of the circuits may be arranged maintaining a predetermined distance from the end 3 of the substrate. As shown in FIGS. 3 to 5, however, a plurality of ends may be arranged maintaining different distances. In these cases, too, the ends 4 of the circuits may be of nonlinear shapes as shown in FIGS. 4 and 5. FIGS. 2 to 5 illustrate some shapes near the end of the circuit board, wherein Drawings (a) illustrate wiring shapes of the first circuit boards, Drawings (b) illustrate wiring shapes of the second circuit boards, and Drawings (c) illustrate wiring shapes in the connected state. As shown, the areas of contact portions are only portions of wirings. Therefore, the pressure increases at the time of thermocompression bonding and the connection becomes reliable. The nonlinear wirings can be also easily formed relying upon the lithography technology. When the wirings of at least one side are of a nonlinear shape, the length over which the wirings of the first circuit board and the wirings of the second circuit board are overlapped one upon the other is substantially determined by the widths of the wirings. Therefore, the overlapping length of the wirings viewing from the side surface in the lengthwise direction thereof is not important.

The material of the conducting wiring may be such a conductor as solder (e.g., Sn—Ag—Cu), copper, nickel, gold, aluminum or tungsten. From the standpoint of easy connection, further, the surface may be finished by being plated with such a material as tin, gold, nickel or nickel/gold (two-layer plating). The substrate of the FPC may be a resin film that is usually used for the FPC, such as a polyimide film.

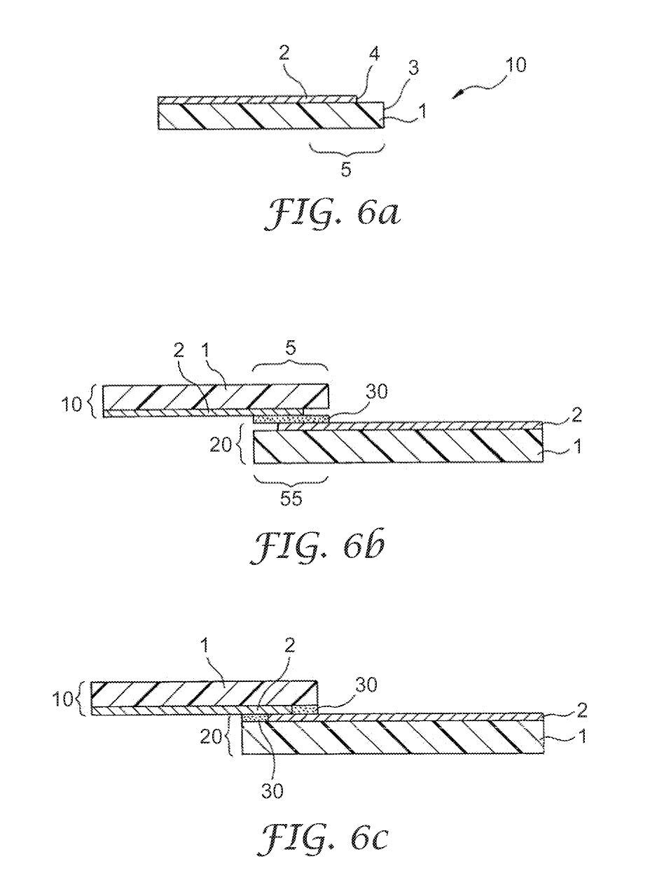

The method of connecting the circuit boards of the invention will be described below in order of steps. FIG. 6 is a view of steps illustrating the connection method of the present invention. First of all, a first circuit board 10 (e.g., flexible printed circuit board (FPC)) is provided forming conductor wirings 2 on a substrate 1 (e.g., resin film)(step (a)). Next, a second circuit board 20 is provided to which the first circuit board 10 is to be connected. A connection portion 5 of the first circuit board 10 is brought in position with a connection portion 55 of the second circuit board 20, and is overlapped thereon via an adhesive sheet 30 (step (b)). Here, the ends of the wirings are terminated at the end 4 of the circuit on the inside of the end 3 of the substrate. Besides, the wirings are overlapped on relatively small areas near the end 4 of the circuit. The adhesive sheet 30 is so arranged as to be present even in the portions where there is no circuit between the end 3 of the substrate and the end 4 of the circuit. Namely, the adhesive sheet 30 is arranged on a region where the circuit of the first circuit board 10 is overlapped on the circuit of the second circuit board 20 and, further, on a region where the substrate portion without the circuit on the outer side thereof is overlapped on the circuit. Here, the adhesive sheet 30 does not need to cover the whole surfaces of the substrate without the circuit between the end 3 and the end 4, but may cover at least part thereof. A laminated body of the first circuit board 10, the adhesive sheet 30 and the second circuit board 20 thus overlapped is at least partly and thermocompressively bonded together simultaneously over the region where the wirings are overlapped and over the region where the adhesive is existing on the outer side thereof to thereby accomplish an electric connection between the connection portion 5 of the first circuit board 10 and the connection portion 55 of the second circuit board 20 (step (c)). The adhesive sheet 30 may be thermally laminated in advance on the connection portion of the first circuit board 10 or of the second circuit board 20.

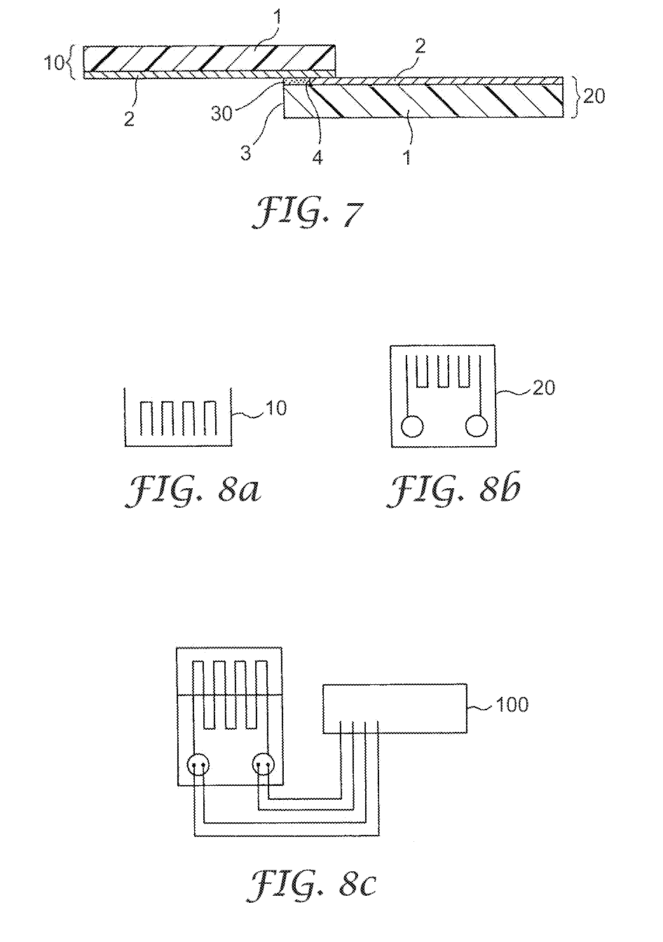

FIG. 7 is a sectional view illustrating another embodiment of the structure connected by the method of connecting circuit boards of the present invention. In the second circuit board 20 of this embodiment, the ends of wirings are terminated at an end 4 of the circuit on the inside of the end 3 of the substrate while in the first circuit board 10, the ends of wirings are terminated at the end same as the end of the substrate. When the circuit board is a flexible board, this flexible board is desirably the first circuit board 10. When the flexible board is deflected, a peeling force is exerted on the end 3 of the second circuit board 20. This is because the first circuit board 10 and the second circuit board 20 are strongly adhered together with an adhesive of the adhesive sheet 30.

The thermocompression bonding can be executed by using a heat bonder capable of heating and pressing, such as a constant heat bonder, a pulse heat bonder or a ceramic heat bonder. When the heat bonder is used, the laminated body of the first circuit board, second circuit board and adhesive sheet laminated one upon the other is placed on a support plate having a low heat conductivity such as of a quartz glass, and a bonder head that is heated is arranged on the laminated body and is pressed thereon to accomplish the thermocompression bonding. It is desired that the first circuit board or the second circuit board is pressed by the bonder head via an elastic sheet having heat resistance, such as a polytetrafluoroethylene (PTFE) film or a silicone rubber. When the circuit board on the side of the bonder head is the FPC, the elastic sheet that is inserted causes the resin film of the FPC to be pushed at the time of thermocompression bonding, and a stress (spring back) is produced by the deflection of the resin film of the FPC. After the adhesive film is cured, the FPC maintains the deflected state. Therefore, a contact pressure is maintained in the connection portion improving the stability of connection. The thermocompression bonding is effected by being compressed by using flat plates that are heated. The temperature and pressure of thermocompression bonding is determined depending upon the resin composition of the adhesive sheet that is selected, and there is no limitation. However, the thermocompression bonding is, usually, executed at a temperature of about 150 to 250° C. under a pressure of 8 to 12 MPa (pressure of 10 MPa) for 0.5 to 15 seconds.

The present invention usually uses the adhesive sheet containing a thermoplastic adhesive component which softens at about 100° C. or higher. Depending upon the cases and more preferably, the adhesive sheet further contains a thermosetting component so as to be cured by heating. The thermosetting component can be cured at about 80° C. to about 250° C. By effecting the step of curing desirably at the above temperature for several minutes to several hours, the adhesive sheet forms a connection featuring a further increased heat resistance and strength.

Next, described below is the adhesive sheet used in the present invention. The invention uses the adhesive sheet containing a thermoplastic adhesive component which softens when heated at a given temperature. Depending upon the cases, the adhesive sheet is a thermoplastic and thermosetting adhesive sheet that cures when it is further heated. The softening and thermosetting adhesive component is a resin containing both the thermoplastic component and the thermosetting component. According to the first embodiment, the thermosoftening and thermosetting resin can be a mixture of a thermoplastic resin and a thermosetting resin. According to a second embodiment, the thermosoftening and thermosetting resin can also be a thermosetting resin modified with a thermoplastic component. As the second embodiment, there can be exemplified an epoxy resin modified with a polycaprolactone. According a third embodiment, the thermosoftening and thermosetting resin can be a polymer resin having a thermosetting group such as an epoxy group on a basic structure of the thermoplastic resin. As the above polymer resin, there can be exemplified a copolymer of an ethylene and a glycidyl (meth)acrylate.

The adhesive sheet that can be used in the present invention, desirably, has a viscosity, at a heating temperature (e.g., 150 to 250° C. or, for example, at 200° C.) at the time of connection, in a range of 100 to 50,000 Pa·s, more preferably, in a range of 1,000 to 50,000 Pa·s and, further preferably, in a range of as high as 10,000 to 50,000 Pa·s. The “viscosity of the adhesive sheet” is calculated from the thickness (h(t))(meters (m)) of the adhesive sheet when a circular sample of the adhesive sheet having a radius, r (meters (m)), is arranged between two pieces of horizontal flat plates while exerting a predetermined load F(N) thereon at a measuring temperature T(° C.) and after a time t (seconds) has passed. It is calculated from the following formula, h(t)/h₀=[(4h₀²Ft)/(3πηr⁴)+1]^{-1/2} (wherein hₒ is an initial thickness (meter (m)) of the adhesive sheet, h(t) is a thickness (meter (m)) of the adhesive sheet after t seconds, F is a load (N), t is a time (seconds) from when the load F is exerted, η is a viscosity (Pa·s) at the measuring temperature T (° C.), and r is a radius (meter (m)) of the adhesive sheet).

In the present invention, it is desired to select the viscosity to lie in the above range because of the reasons described below. When the viscosity at 150 to 250° C. is 100 Pa·s or greater and, particularly preferably, 1,000 Pa·s or greater, the adhesive sheet acquires a sufficiently large viscosity when thermocompressively bonded at 150 to 250° C. in a short period of time. When the circuit board is the FPC as described above, therefore, a stress (spring-back effect) is obtained due to the deflection of the resin film of the FPC, and stability of connection can be maintained. For example, when the resin film is a polyimide film having a thickness of 25 μm, a good connection stability is obtained if the adhesive sheet has a viscosity at 150 to 250° C. of not smaller than 100 Pa·s and, particularly preferably, not smaller than 1,000 Pa·s. When the adhesive sheet has a too great viscosity, on the other hand, a high pressure and a high temperature are required to expel the resin from between the wiring conductors in the connection portions. When the adhesive sheet has a viscosity at 150 to 250° C. of not greater than 50,000 Pa·s, the connection between the conductors can be established relatively easily through the thermocompression bonding under the above-mentioned pressure.

An epoxy resin can be contained as the thermosetting adhesive component. As the epoxy resin, there can be used, for example, polycaprolactone-modified epoxy resin, bisphenol A-type epoxy resin, bisphenol F-type epoxy resin, bisphenol A diglycidyl ether-type epoxy resin, phenolnovolak-type epoxy resin, cresolnovolak-type epoxy resin, fluorene epoxy resin, glycidylamine resin, aliphatic epoxy resin, brominated epoxy resin or fluorinated epoxy resin. Though there is no limitation, it is desired that the epoxy resin is contained in an amount of not larger than 30% by mass of the adhesive composition.

The adhesive composition may, depending upon the cases, contain an aromatic polyhydroxy ether resin which, desirably, has a weight average molecular weight (Mw) of 10,000 to 5,000,000. When the molecular weight is too low, the connection portion is often broken at high temperatures. When the molecular weight is too high, on the other hand, the adhesive composition cannot be suitably fluidized in conducting the thermocompression bonding operation. The weight average molecular weight (Mw) is measured by gel permeation chromatography (GPC) (standard polystyrene as a reference). Though there is no limitation, it is desired that the ether resin is contained in an amount of not larger than 50% by mass of the adhesive composition.

The adhesive composition may, further, contain other components as required. For example, there may be contained a flexible compound such as rosin for preventing the oxidation of metals, a chelating agent (ethylenediamine tetraacetate (EDTA), etc.) that works as a rust-preventing agent, Schiff base, a cure-accelerating agent for the epoxy resin, dicyandiamide (DICY), organic acid hydrazide, amine, organocarboxylic acid, polymercaptane-type curing agent, phenols and isocyanate.

Desirably, the adhesive composition can contain an imidazolesilane compound which includes an alkoxysilyl group and an imidazole group in the molecules thereof. The silanol group formed by the hydrolysis of the alkoxysilyl group easily forms a covalent bond with the OH group in the aromatic group-containing polyhydroxy ether resin.

The thermosetting adhesive composition is capable of adding organic particles in an amount of 15 to 100 parts by weight to 100 parts by weight of the above adhesive composition. With the organic particles being added, the resin exhibits plastic fluidity while the organic particles maintain flexibility of the thermosetting adhesive composition after it has been cured. When heated in the step of connection, water adhered on the first circuit board or on the second circuit board may vaporize to produce a water vapor pressure. Even in this case, the resin is not fluidized to trap the bubbles therein.

The organic particles that are added are those of acrylic resin, styrene/butadiene resin, styrene/butadiene/acrylic resin, melamine resin, melamine/isocyanurate adduct, polyimide, silicone resin, polyetherimide, polyethersulfone, polyester, polycarbonate, polyether ether ketone, polybenzoimidazole, polyarylate, polyarylate, liquid crystal polymer, olefin resin or ethylene/acrylic copolymer, the sizes thereof being not larger than 10 μm and, desirably, not larger than 5 μm.

### EXAMPLES

### Example 1

### 1. Adhesive Sheet

First, as the thermoplastic adhesive component used for the adhesive composition that constitutes the adhesive sheet, a fluorenebisphenolpolyhydroxy ether resin (PHE 1) was prepared as described below.

100 Grams of a fluorenebisphenol(4,4′-(9-fluorenylidene)diphenol), 100 g of a bisphenol A diglycidyl ether (DER 332 (trade name): epoxy resin available from Dow Chemical Japan Co., epoxy equivalent: 174) and 300 g of a cyclohexanone were introduced into a 2-liter separable flask with a refluxing device, and were completely dissolved at 150° C. While stirring the solution with a screw, 16.1 g of a cyclohexanone solution of a triphenylphosphine (6.2% by weight) was added thereto dropwise, and was heated at 150° C. for 10 hours while continuing the stirring. The obtained polymer was measured for its molecular weight by using a tetrahydrofuran (THF) solution by a gel permeation chromatography (GPC) with a standard polystyrene to have a number average molecular weight (Mn) of 24,000 and a weight average molecular weight (Mw) of 96,000.

The obtained polyhydroxy ether resin (PHE 1) was a polymer having the following recurring unit.

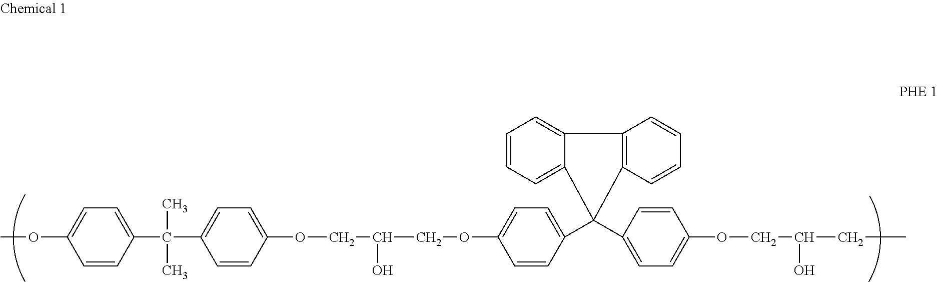

The above PHE 1 (24 parts by mass) as well as acrylic particles (70 parts by mass) as organic particles (EXL 2314: PARALOID (trademark) EXL available from Rohm and Haas Co.), epoxy resin (6 parts by mass)(YD128: available from Toto Kasei Co., epoxy equivalent: 180) and an imidazolesilane (0.4 parts by weight)(IS1000: available from Nikko Materials Co.) as a catalyst, were dissolved and dispersed in a mixed solvent of 500 g of the tetrahydrofuran (THF) and 20 g of a methanol to thereby obtain an adhesive composition.

A polyester film treated with silicone was coated with the adhesive composition prepared above and was dried to form an adhesive sheet of a size of 13 mm×2 mm and a thickness of 30 μm.

Separately, further, a piece of sample thereof of 30 mm×5 mm×0.06 mm was prepared for measuring Tg and another piece of circular sample of a radius (m): 5×10⁻³ (m) was prepared for measuring the viscosity.

Tg was measured as described above by using RSA (trade name) manufactured by Rheometrics Co. to be 132° C. As a result of measuring the viscosity, further, a circular sample of the adhesive sheet of a radius (r) 5×10⁻³ (meters (m)) was arranged between two pieces of horizontal flat plates, and a constant load (F) 1296 (N) was exerted thereon at a measuring temperature (T) of 240 (° C.). In compliance with the formula h(t)/h₀=[(4h₀²Ft)/(3πηr⁴)+1]^{-1/2} (wherein h₀ is an initial thickness (meter (m)) of the adhesive sheet, h(t) is a thickness (meter (m)) of the adhesive sheet after t seconds, F is a load (N), t is a time (seconds) from when the load F is exerted, η is a viscosity (Pa·s) at the measuring temperature T° C., and r is a radius (meter (m)) of the adhesive sheet), the viscosity at 240° C. was calculated to be 34,000 Pa·s.

### 2. Circuit Boards

As a first circuit board, use was made of a flexible printed circuit board (FPC), ESPANICS M (trade name) manufactured by Shin-Nittetsu Kagaku Co. (25 μm polyimide substrate, constitution at the connection end: connection circuit pattern, fifty lines extending in parallel toward the end of the substrate maintaining line/gap=100 μm/100 μm, the lines were formed by plating non-electrolytic 3 μm Ni (nickel) on 18 μm electrolytic copper and, further, plating non-electrolytic 0.05 μm Au (gold) thereon, the distance from the end of the circuit to the end of the substrate being 1.35 mm). The circuit on the circuit board 10 was as shown in FIG. 8(a).

As a second circuit board, use was made of a glass cloth epoxy board (FR-4)(glass epoxy substrate of 400 μm thick, constitution at the connection end: connection circuit pattern, fifty lines extending in parallel toward the end of the substrate maintaining line/gap=100 μm/100 μm the lines were formed by plating non-electrolytic 3 μm Ni (nickel) on 18 μm rolled copper and, further, plating non-electrolytic 0.05 μm Au (gold) thereon, the distance from the end of the circuit to the end of the substrate being 1.75 mm). The circuit on the circuit board 20 was as shown in FIG. 8(b).

### 3. Thermocompression Bonding

The above-mentioned glass cloth epoxy board (FR-4), the adhesive sheet and the flexible printed circuit board (FPC) were overlapped in this order on the quartz glass and, thereafter, a polytetrafluoroethylene (PTFE) film of a thickness of 25 μm was arranged thereon. A ceramic head (contact area of 40×3 mm) heated at 255° C. was thermocompressively bonded onto the PTFE film with a load of 220 newtons. The time required for the thermocompression bonding was 12 seconds. The above pressure was reached in less than one second and was maintained constant, while the temperature of the adhesive sheet has reached 210° C. within 3 seconds and was maintained constant. After 12 seconds have passed, the ceramic head was liberated from the load and was left to cool. The overlapping length of the circuit was 0.4 mm.

### 4. Measuring the Resistance

### 4.1. Samples for Testing the Heat Shocks

The circuits connected as described above were subjected to the heat shock testing at 125° C. and at −55° C. (heat shock conditions: 125° C., 30 minutes; −55° C., 30 minutes; time for transfer between the jars, one minute or less). The test samples were measured at 0 time (before the testing), after 100 heat shock cycles, after 250 heat shock cycles and after 500 heat shock cycles.

### 4.2. Samples for Testing the Thermal Aging

The circuits connected as described above were tested for their thermal aging at 85° C. and 85% RH (relative humidity). The test samples were measured after 0 time (before the testing) and after 500 hours had passed.

### 4.3. Method of Measuring the Resistances

The resistances were measured relying upon the four-terminal method by using a resistance measuring device 100, 34420A (trade name) manufactured by Agilent Co. as shown in FIG. 8. FIG. 8(c) illustrates the manner of connecting the connected circuit to the resistance measuring device 100.

### 4.4. Results

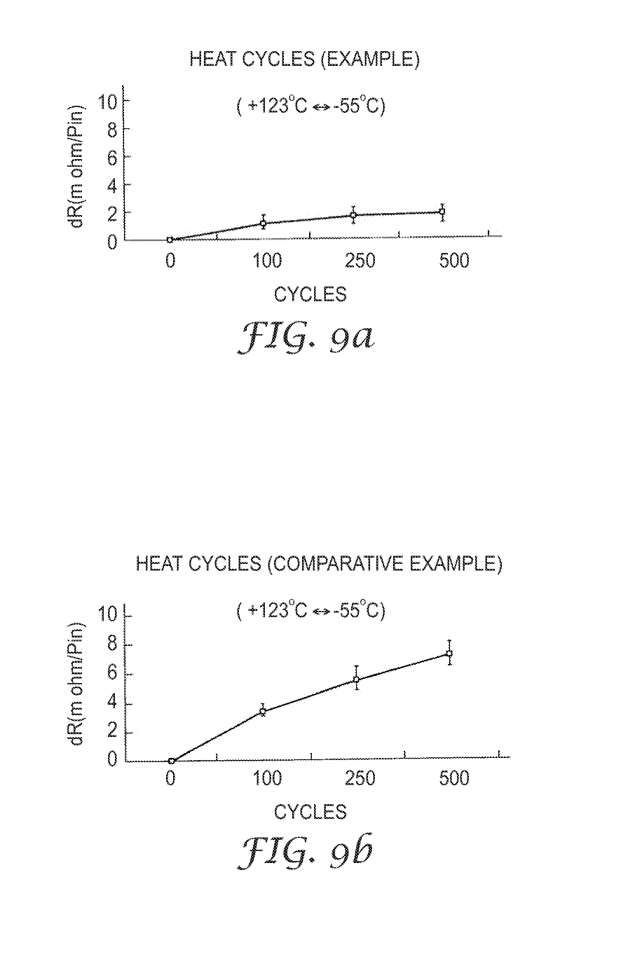

FIG. 9 shows the results of the heat shock testing. The results were expressed as a difference (ΔR) between the resistance of the sample of before the testing and the resistance after the testing was conducted for a predetermined period of time (FIG. 9(a)). The graph was in milliohms/pin (mΩ/pin) being converted into a resistance per a pin. After the thermal aging testing of 500 hours, an increase in the resistance was 2.8 Ωm)/pin.

### Comparative Example 1

The first circuit board and the second circuit board were the ordinary circuit boards having ends of wirings extending up to the ends of a substrate. When the overlapping length of wiring was selected to be 2 mm, the electric connection could not be accomplished under the same connection conditions as in Example 1. Next, the connection was effected by elevating the temperature of the adhesive film portion by 20° C. FIG. 9(b) shows the results of measuring the resistances after the heat shock testing. The graph was in milliohms/pin (mΩ/pin) being converted into a resistance per a pin. After the thermal aging testing of 500 hours, an increase in the resistance was 5.2 mΩ/pin.

### Example 2

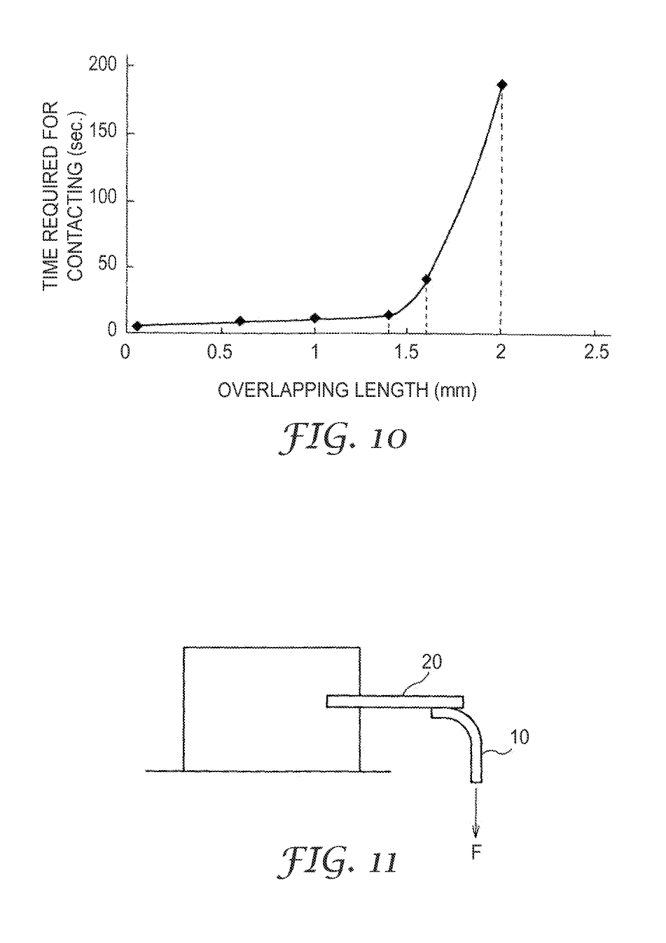

The connection was effected in the same manner as in Example 1 at a temperature of 210° C. under a pressure of 180 N but selecting the overlapping length of the circuits to be 0.05 mm, 0.6 mm, 1.0 mm, 1.4 mm 1.6 mm and 2.0 mm. The times were measured until the conductors of the connection portions came in contact. The results were as shown in FIG. 10. The times until the contacting were determined by confirming the conduction by measuring the resistance.

Under the above thermocompression bonding conditions, it was learned that the connection was easily accomplished within short periods of time when the overlapping length was 1.4 mm or less.

### Example 3

The connection was effected in the same manner as in Example 1, but selecting the overlapping length of conductors of the connection portions to be 0.2 mm. As shown in FIG. 11, the second circuit board 20 of the sample was fixed at a horizontal position, and a mass of 70 grams was hung from the end of the first circuit board 10 on the side opposite to the end of the circuit thereof.

After 30 seconds have passed, no delamination was seen in the region connected with the adhesive, from which it was learned that a good connection could be maintained.

1. A method of connection comprising:
opposing a first circuit board having one or more first circuits provided on a substrate thereof to a second circuit board having one or more second circuits provided on a substrate thereof via an adhesive sheet containing a thermoplastic adhesive component in a manner that said first circuit is partly overlapped on part of said second circuit, and that said adhesive sheet is partly arranged on a region where said first circuit and said second circuit are overlapped one upon the other to thereby obtain a laminated body of said first circuit board, said adhesive sheet and said second circuit board; and
accomplishing electric conduction between said first circuit and said second circuit by applying heat and pressure to the laminated body of said first circuit board, said adhesive sheet and said second circuit board;
wherein an end of the circuit formed on at least either said first circuit board or said second circuit board is terminated at a position separated away from an end of the substrate; and
the adhesive of said adhesive sheet is partly arranged between the end of said substrate of said circuit board and the end of said circuit so as to be adhered to the opposing circuit board.

2. The method of connection according to claim 1, wherein the ends of both of said first circuit and said second circuit are of a linear shape, and the length of wiring in a region where said first circuit and said second circuit are overlapped one upon the other is 0.05 to 1.4 mm.

3. The method of connection according to claim 1, wherein the end of at least either one of said first circuit or said second circuit is of a nonlinear shape.

4. The method of connection according to claim 1, wherein the viscosity of the adhesive sheet at a temperature of when being heated is 1,000 to 50,000 Pa·s, and the glass transition temperature (Tg) thereof is 60° C. to 200° C.

5. The method of connection according to claim 4, wherein the temperature of the adhesive sheet portion when being heated is 150 to 250° C.

6. The method of connection according to claim 1, wherein the adhesive component in the adhesive sheet includes a thermoplastic adhesive component as well as a thermosetting adhesive component, and is cured at the time of being connected and/or after connected.

7. The method of connection according to claim 1, wherein the conductor wirings constituting the circuits of the circuit boards are treated on the surfaces thereof by being plated with tin, gold, nickel, or with two layers of nickel and gold.

8. The method of connection according to claim 1, wherein at least either one of said first circuit board or said second circuit board is a flexible circuit board.

9. A connected structure produced by the connection method of claim 1.
